(19) United States
(12) Patent Application Publication
(10) Pub. No.: US 2026/0096455 A1
(43) Pub. Date: Apr. 2, 2026

(54) MULTI-TIERED DEVICE HAVING AN ALIGNED THROUGH-VIA AND METHODS OF FORMING THE SAME

(71) Applicant: Taiwan Semiconductor Manufacturing Company Limited, Hsinchu (TW)

(72) Inventors: Chen-Shien Chen, Zhubei City (TW); Chi-Yen Lin, Tainan City (TW); Feng-Chang Hsu, Hsinchu (TW); Ting Hao Kuo, Hsinchu City (TW); Hsu-Hsien Chen, Hsinchu City (TW)

(21) Appl. No.: 18/900,694

(22) Filed: Sep. 28, 2024

(51) Int. Cl. H01L 23/498; H01L 23/544

(52) U.S. Cl. CPC H10W 70/635; H10W 46/00; H10W 90/701; H10W 46/301

(57) ABSTRACT

A semiconductor device includes a first-tier structure and a second-tier structure. The first-tier structure includes a silicon portion with through-vias formed through the silicon portion after a back end of line process. The first-tier structure is attached to a first carrier that includes an alignment mark used to form the through-vias and the corresponding backside bump pad metal that are aligned with the through-vias at locations based on the alignment mark. The second-tier structure is bonded to the first-tier structure with the backside bump pad metals interposed between the two tiers. In some embodiments, the through-vias are a reverse pillar shape with a bottom recess and a specified ratio between a top portion and bottom portion.

### BACKGROUND

The semiconductor industry has grown due to continuous improvements in integration density of various electronic components (e.g., transistors, diodes, resistors, capacitors, etc.).

In addition to smaller electronic components, improvements to the packaging of components have been developed in an effort to provide smaller packages that occupy less area than previous packages. Example approaches include quad flat pack (QFP), pin grid array (PGA), ball grid array (BGA), flip chips (FC), three-dimensional integrated circuits (3DICs), wafer level packages (WLPs), package on package (PoP), System on Chip (SoC) or System on Integrated Circuit (SoIC) devices. Some of these three-dimensional devices are prepared by placing chips over chips. These three-dimensional devices provide improved integration density and other advantages because of the decreased length of interconnects between the stacked chips. However, there are many challenges related to three-dimensional devices, including alignment of the multi-tier devices.

For example, through-vias (e.g., thru-silicon vias) are originally patterned and etched based on overlay marks, alignment marks, or backside marks. During a subsequent dicing and placing process, the reference mark (i.e., overlay marks, alignment marks, or backside marks) that had been used to align the through-vias and first carrier are no longer physically correlated. Thus, alignments based on the previous reference marks are no longer present and may not ensure accurate and/or proper future alignment. To further complicate the issue, a backside bump pad metal (BSBPM) is typically formed on the through-vias using alignment marks on a second carrier or substrate (i.e., not the alignment marks on the first carrier that were used to locate and form the through-vias). Therefore, for the forgoing reasons, the through-vias and BSBPMs are commonly misaligned.

As a result, current system on an integrated chip (SoIC) devices commonly suffer from overlay (OVL) shifts between tiers. The OVL shift may occur due to poor alignment where the physical center of a component and an identified center may differ due to die shifting. Depending on the amount of misalignment, the device may require additional processing to be effective or, in some instances, the misalignment may cause significant loss of accuracy and make the device unusable.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of an intermediate semiconductor device with a first-tier structure according to various embodiments of the present disclosure.

FIG. 2 is a vertical cross-sectional view of an intermediate semiconductor device with a first-tier structure bonded to a first carrier wafer including an alignment mark according to various embodiments of the present disclosure.

FIG. 3 is a vertical cross-sectional view of an intermediate semiconductor device after applying a gap fill according to various embodiments of the present disclosure.

FIG. 4 is a vertical cross-sectional view of an intermediate semiconductor structure device after chemical mechanical polishing of a first-tier structure according to various embodiments of the present disclosure.

FIG. 5A is a vertical cross-sectional view of an intermediate semiconductor structure device with a plurality of through-vias formed in the first-tier structure with a blown-up view of the through-via according to various embodiments of the present disclosure.

FIG. 5B is a top-view of an intermediate semiconductor device with through-vias as shown in FIG. 5A according to various embodiments present disclosure.

FIG. 6 is a vertical cross-sectional view of an intermediate semiconductor device after an etch-back process with at least two through-vias according to various embodiments of the present disclosure.

FIG. 7A is a vertical cross-sectional view of an intermediate semiconductor device after backside bump pad metal (BSBPM) layers are formed and aligned with the through-vias according to various embodiments of the present disclosure.

FIG. 7B is a top-view of an intermediate semiconductor device with backside bump pad metal layers aligned with through-vias as shown in FIG. 7A according to various embodiments present disclosure.

FIG. 8 is a vertical cross-sectional view of an intermediate semiconductor device with a first-tier structure bonded to a second-tier structure according to various embodiments of the present disclosure.

FIG. 9 is a vertical cross-sectional view of an intermediate semiconductor device bonded to a second carrier wafer according to various embodiments of the present disclosure.

FIG. 10 is a vertical cross-sectional view of an intermediate semiconductor device after debonding a first carrier wafer and flipping the intermediate semiconductor device along a horizontal axis according to various embodiments of the present disclosure.

FIG. 11 is a vertical cross-sectional view of an intermediate semiconductor device after a passivation layer and a polyimide layer are formed according to various embodiments of the present disclosure.

FIG. 12 is a vertical cross-sectional view of an intermediate semiconductor device after bump formation according to various embodiments of the present disclosure.

FIG. 13A is a vertical cross-sectional view of a portion of a semiconductor device with improved alignment between the through-vias and backside bump pad metal layers according to various embodiments of the present disclosure.

FIG. 13B is a vertical cross-sectional view of an alternative embodiment of a portion of the semiconductor device with improved alignment between the through-vias and backside bump pad metal layers according to various embodiments of the present disclosure.

FIG. 14 is a flowchart illustrating a method of forming a portion of a semiconductor device with through-vias according to an embodiment of the present disclosure.

FIG. 15 is a flowchart illustrating a method of aligning through-vias with backside bump pad metal layers in a semiconductor device according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein are directed to semiconductor devices, and specifically to multi-tier semiconductor devices. The multi-tier semiconductor devices may include at least one semiconductor integrated circuit (IC) die bonded to a carrier structure, which may be, for example, a substrate, an interposer, another semiconductor die or a semiconductor wafer. The at least one semiconductor IC die may be bonded to the carrier structure in a configuration such as a system on integrated chip (SoIC), chip on wafer on substrate (CoWoS), chip on wafer (CoW), etc. Such multi-tier device semiconductor devices may increase the density of devices that may occupy a given planar area or “footprint.”

Semiconductor IC dies may include a semiconductor material substrate, such as a silicon substrate, having a number of circuit components and elements formed on and/or within the semiconductor material. Semiconductor dies are typically fabricated by sequentially depositing insulating or dielectric layers, conductive layers, and semiconductive layers of material over a semiconductor substrate (e.g., a wafer), patterning the various material layers using lithography to form integrated circuits, and separating individual dies from the substrate such as by sawing between the integrated circuits along scribe lines.

The first-tier structure of a multi-tier semiconductor device may be configured to integrate various components and interconnects on a silicon substrate with precise positioning accuracy. The process may form individual components such as transistors, capacitors, resistors, or other devices using techniques like chemical-mechanical planarization (CMP), shallow trench isolation (STI) for forming isolation structures, well formation for transistor creation, source and drain module fabrication, surface treatment to prepare contacts for metallization. Additional processes then deposits metal interconnect layers onto the wafer through a pick-and-place (PnP) assembly of components.

Silicon dioxide or other dielectric materials are deposited as an insulating layer between adjacent conductive lines to prevent electrical shorts and ensure reliable connections. The CMP process may be used to planarize these insulating layers by removing excess material through a combination of chemical etching and abrasive polishing. Silicon nitride or other barrier materials may be deposited as an adhesion layer between metal interconnects for improved electrical conductivity while minimizing conductive material diffusion. Another process may also involve depositing dielectric layers with precise thickness control to ensure optimal spacing and alignment of components.

A device structure may be formed by placing a first device structure (e.g., an IC die) onto a carrier structure in a “face down” configuration such that integrated circuit components formed on a first (i.e., front) side of a semiconductor substrate of the first device structure face towards a surface of the carrier structure (e.g., carrier wafer). A bonding process may be used to bond bonding features on the first device structure to corresponding bonding features on the carrier structure.

In some embodiments, a device structure may include multiple levels, or “tiers,” of device structures. For example, an IC die may be bonded to a carrier structure, as described above. A second IC die may then be bonded over the second (i.e., back) side of the first IC die, a third IC die may be bonded over the second IC die, and so forth, to provide a multi-tiered bonded device structure.

A bonded multi-tiered device structure may be formed by placing a second device structure (e.g., a semiconductor substrate or die, optionally having integrated circuits formed thereon) onto first device structure (e.g., a separate semiconductor substrate or die, optionally having integrated circuits formed thereon). A bonding process may be used to bond bonding features on the first device structure to corresponding bonding features on the second device structure. In some embodiments, a direct bonding technique, such as metal-to-metal (M-M) and dielectric-to-dielectric (D-D) bonding techniques, may be used to bond the device structures to form the bonded device structure. In such bonding techniques, bonding layers including an array of metal bonding pads surrounded by a dielectric material may be formed on the structures to be bonded. The bonding layer on the second device structure may be aligned over the corresponding bonding layer on the first device structure, and the two bonding layers may be brought into contact with one another. This may result in a chemical pre-bond between the dielectric material of the respective bonding layers. An annealing process may then be performed to promote bonding of the metal bonding pads of the respective bonding layers, thereby producing metal bonds extending between the first device structure and the second device structure. Other types of bonding processes, such as a fusion bonding process between dielectric bonding material layers, may also be utilized.

A dicing process may be used to separate portions of the bonded device structure to form individual bonded die structures, where each bonded die structure may include a stack of two or more semiconductor IC dies that are bonded together. The dicing process typically utilizes a metal blade (e.g., a dicing saw) to mechanically saw through the various layers of the bonded device structure to separate individual bonded die structures.

The processing of each tier may involve forming multiple layers with precise alignment using techniques like photolithography, dry etching, wet chemical processing for creating physical marks such as overlay alignment marks (OAM) that serve as reference points during subsequent fabrication steps. These OAMs may be configured to provide accurate positioning and registration of components in each tier structure. Multiple layers may be formed with precise spacing control using techniques like CMP or chemical-mechanical polishing for planarization purposes while maintaining electrical conductivity through adhesion layer formation between metal interconnects. The surface roughness and flatness are useful during this process due to the impact on electrical connections.

The alignment mark is a useful component in multi-tier semiconductor devices that enables precise positioning and registration of subsequent components within each tier structure. The OAM serves as a reference point for precise positioning of subsequent components in each tier structure. The mark may be formed using photolithography techniques to create physical marks on the surface. Multiple types of alignment marks with different purposes are feasible and may include separate layers that are used to form through-vias versus alignment marks that are used to form capping layers. For instance, through-vias require a specific type of mark that is detectable by scanners during grinding or drilling processes to ensure accurate positioning within the silicon portion. Alignment marks may be created using various techniques like dry etching, wet chemical processing, and plasma dicing process for end portions formation in subsequent tiers. These marks serve as reference points for aligning components in each layer, ensuring consistent spacing and orientation between layers.

During formation of the bonded semiconductor devices, features may become misaligned due to shifting. For example, current SoIC devices commonly suffer from overlay (OVL) shifts between the multiple bonded tiers. The OVL shift occurs due to poor alignment between the physical center of the each of the tiers and from an identified center that differs from the physical center. The physical center and identified center may differ due to die shifting that occurs during the creation of the first-tier structure.

For example, the first-tier structure may include a through-via that may be formed during processing steps (e.g., fabricating and patterning individual components such as transistors, capacitors, or resistors). In instances in which the through-vias are formed during the processing, the position of the through-vias are aligned using an alignment mark made during the original processing steps. The through-vias formed during this process may be known as via-first through-vias. The through-vias are normally used for interconnectors and commonly impact thermo-mechanical stress causing design and manufacturing problems.

Alternatively, in instances in which the through-vias are formed after initial processing and during additional processing (e.g., depositing metal interconnect layers on a substrate or wafer after the device has been patterned) the through-vias are aligned using an alignment mark made during the additional processing steps, such as a metal alignment mark at a scribe area. The through-vias formed during these process may also be known as via-middle through-vias. These through-vias are commonly used for advanced 3D ICs and interposer stacks.

For both the through-vias formed during the initial processing and the additional processing, when a backside bump pad metal (BSBPM) layer is formed on the first-tier structure, there is no longer a correlation between the through-vias and the BSBPM layers. As a result, the through-vias and the BSBPM structures are often misaligned. This misalignment may be due to the fact that the through-vias are formed using alignment marks in the different processing steps that are no longer present or properly correlated to the remaining structure when forming the BSBPM layers. Therefore, there exists a misalignment between the through-vias and the BSBPM layers because the alignment marks used to make the through-vias have no physical correlation to the alignment marks used to make the BSBPM layers. Depending on the amount of misalignment, the device may require additional processing to be effective. In some instances, the misalignment may cause significant loss of accuracy and have a negative impact on the device to the point the device may not be viable.

In various embodiments disclosed herein, the through-vias may be formed in a first-tier structure based on an alignment mark located in a first carrier wafer. In some embodiments, the first-tier structure may initially be prepared by creating individual components on a silicon wafer such as transistors, capacitors, and resistors. Additionally, the first-tier structure may undergo a pick-and-place (PnP) process to assemble components on the first-tier structure. The first-tier structure may be placed on a first carrier wafer having an alignment mark and bonded thereto. After the PnP process, the through-vias may be formed through at least a silicon portion of the first-tier structure using the alignment mark located on the first carrier wafer by a through-via-last process. Because the through-vias are formed after the PnP process based on the alignment mark, the BSBPM layers may be aligned to the through-vias during formation based on the same alignment mark that was used to form the through-via. Additionally, since the through-vias are formed by a through-via-last process, the BSBPM layers may be formed directly after or during through-via formation, thereby improving alignment among the through-vias and the BSBPM layers. In some embodiments, a second-tier structure may be bonded to the first-tier structure creating the multi-tier bonded structure that further includes aligned BSBPM layers and aligned bonding pad metal (BPM) layers. Overall, various disclosed embodiments improve the alignment of structures located in the same and different tiers of the semiconductor structure.

In some embodiments, the first-tier structure may be patterned to include individual components on a substrate, such as a silicon wafer. The process may include: selecting a wafer, chemical-mechanical planarization, or polishing (CMP) the wafer surface, performing shallow trench isolation (STI) process to form isolation structures, well formation for different types of transistors, source and drain module formation, and a surface treatment to prepare contacts for metallization. Once the first-tier structure includes the desired structures, the structures may be electrically connected to a circuit.

Additionally, metal interconnect layers may be deposited within the first-tier structure and components may be placed on the first-tier structure through a PnP process. For example, the process may include: silicidation of source and drain regions, adding a dielectric layer to isolate metal and silicon portions, chemical mechanical polishing (CMP) processing to planarize the dielectric layer, creating holes in the dielectric layer, and depositing metals. Through-vias may be formed through portions of the first-tier structure, such as the silicon portion, to create vertical electrically connections between elements.

In some embodiments, the alignment mark may be created on the first carrier wafer. This alignment mark serves as a reference point for precise positioning of elements located in the same tier as well as alignment between elements located in different tiers. The alignment mark further is used as reference point for aligning components in each layer, ensuring consistent spacing and orientation between layers.

For example, the alignment mark on the first carrier wafer may be used as a reference point for patterning photolithographic masks during formation of through-vias as well as the BSBPM formed in a capping layer. This ensures accurate placement of subsequent components atop the through-vias while maintaining precise positioning between elements and tiers. The scanner detects the alignment mark through various techniques like optical microscopy (visible light), infrared imaging, X-ray inspection or electron beam lithography depending on mark design and material properties.

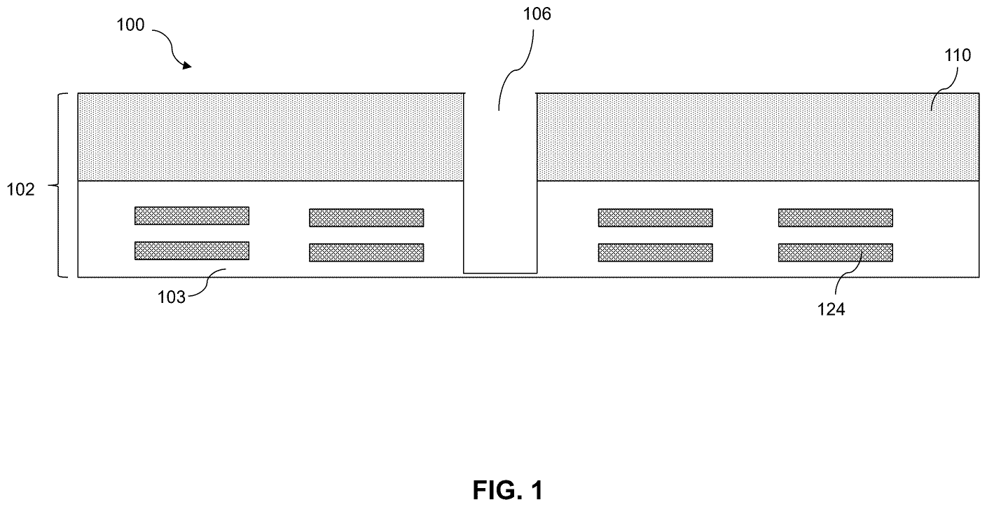

With reference to FIGS. 1-12, the figures show a sequential vertical cross-sectional view illustrating the process of forming the through-vias in a first-tier structure and corresponding BSBPM formed in a capping layer (sometimes referred to as a BSBPM layer) and bonding the first-tier structure to a second-tier structure to create a multi-tiered bonded semiconductor device structure. As mentioned above, disclosed embodiments improve alignment between the through-vias and the BSBPM layer due to the through-vias being formed after the first-tier structure has undergone a PnP process and the alignment mark located on the first carrier wafer.

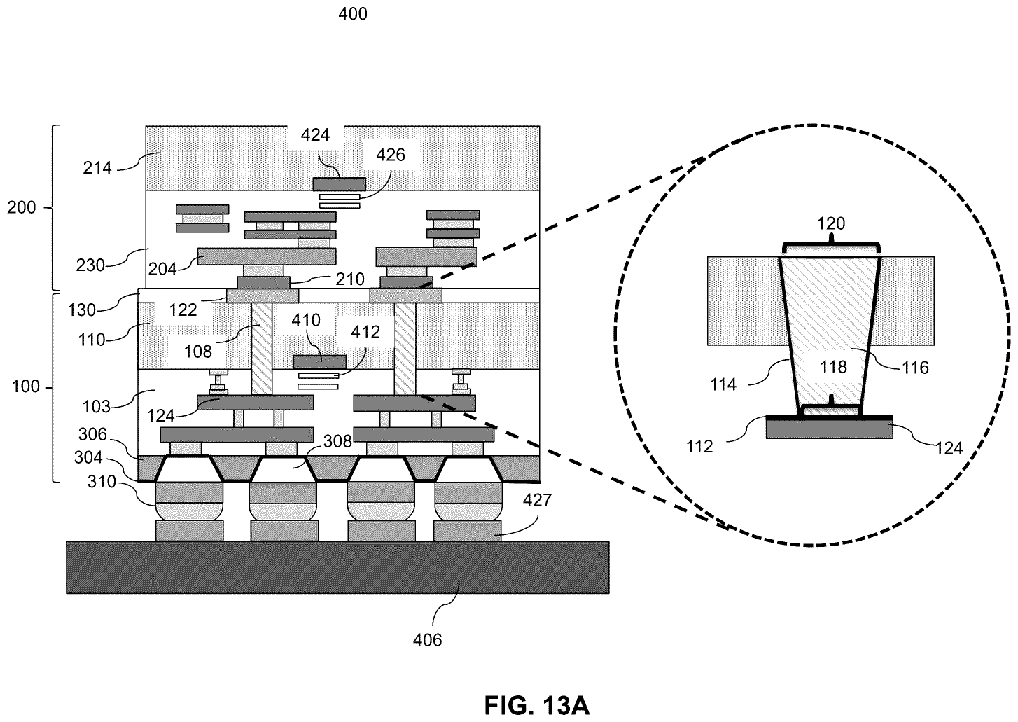

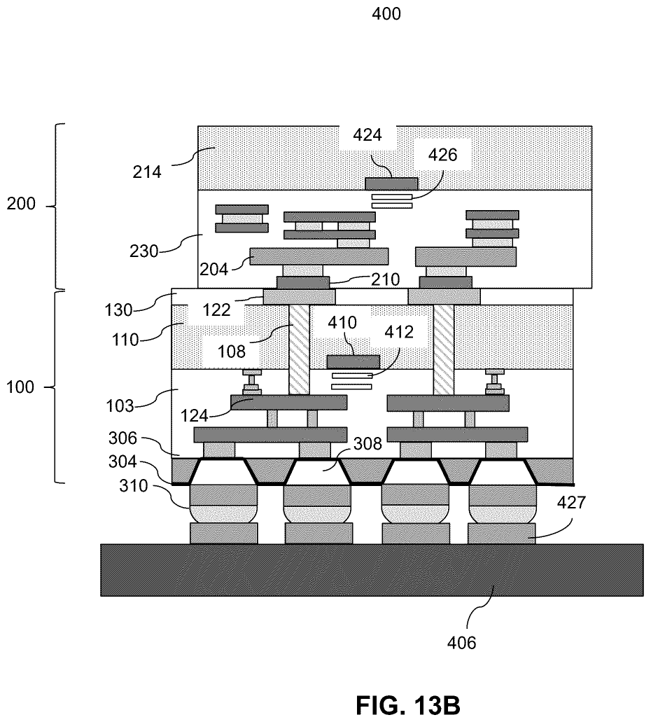

FIG. 1 illustrates a vertical cross-sectional view of an example of a first-tier structure 100 according to various embodiments of the present disclosure. In some embodiments, the first-tier structure 100 may initially undergo a dicing process. As shown, the first-tier structure 100 includes a silicon portion 110 and top metal interconnects 124 formed within a dielectric layer 103 forming a redistribution layer (RDL) 102. The silicon portion 110 may include devices (not shown in FIG. 1) formed within the silicon portion 110. The devices may include a variety of active transistor devices, passive capacitor and/or resistor devices. These devices may be interconnected through the top metal interconnects 124 to each other and/or other components formed in other tier structures. (See FIGS. 13A and 13B) Additionally, the first-tier structure 100 may include an alignment cavity 106 which may be formed during a dicing process. The alignment cavity 106 may separate portions of the first-tier structure 100.

In various embodiments, the dicing process may include a system on a chip (SOC) plasma dicing technique. The plasma dicing process may use a dry etching process using plasma, such as a fluorine plasma. During the plasma dicing process, portions of the first-tier structure 100 may be chemically etched away along the dicing lines. In some embodiments, the plasma dicing may use pulsed plasma dicing, time-multiplexed etching, near-isotropic plasma etching, or passivation layer deposition. In some embodiments, the first-tier structure 100 undergoes dicing using techniques other than plasma dicing, such as blade dicing or laser dicing. The dicing process may result in the alignment cavity 106.

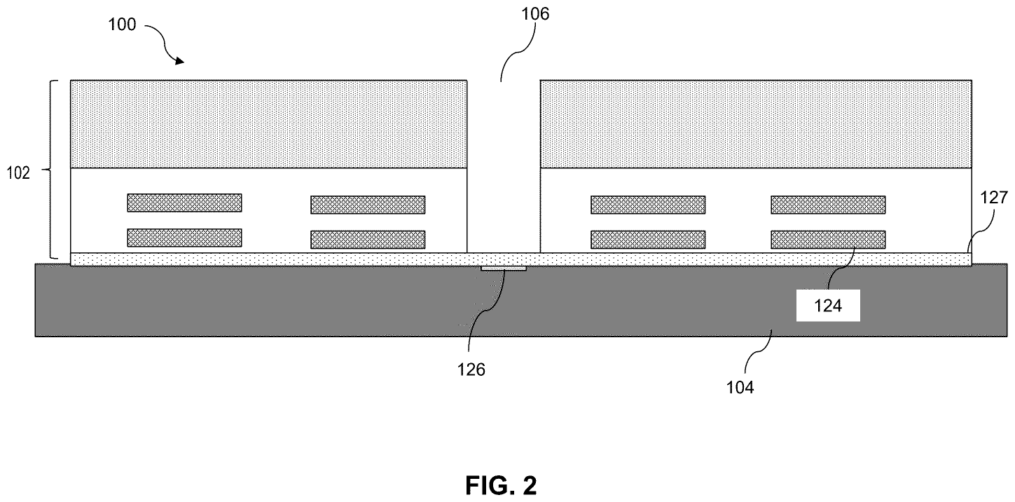

FIG. 2 is a vertical cross-sectional view illustrating the first-tier structure 100 after a bonding process according to various embodiments of the present disclosure. Subsequent to plasma dicing the first-tier structure, a first carrier wafer 104 may be bonded to the first-tier structure 100. In some embodiments, the first carrier wafer 104 may be bonded to the first-tier structure 100 using a fusion bonding process or through an adhesive 127. In some embodiments, the adhesive layer 127 may be an epoxy glue layer used to bond the first carrier wafer 104 and the first-tier structure 100. In other embodiments, the first carrier wafer 104 and the first-tier structure 100 may be bonded using copper micro bumps, copper hybrid bonding, or other appropriate bonding techniques.

Additionally, the first carrier wafer 104 may include an alignment mark 126. The first-tier structure 100 may be located and bonded to the first carrier wafer such that the alignment mark 126 on the first carrier wafer 104 is located within the lateral edges of the alignment cavity 106. In some embodiments, the alignment mark 126 may be an overlay alignment mark or a backside mark on the first carrier wafer 104. In other embodiments, the alignment mark 126 may be an overlay alignment mark, a transistor alignment mark, a metal alignment mark, a die alignment mark, or other appropriate marks on the first carrier wafer 104.

In various disclosed embodiments, the alignment mark 126 may be used to physically correlate the position of the vertical through-vias and the BSBPMs formed in the capping layer. As mentioned above, the alignment mark 126 may be created after the PnP process and before the through-vias are formed in the first-tier structure.

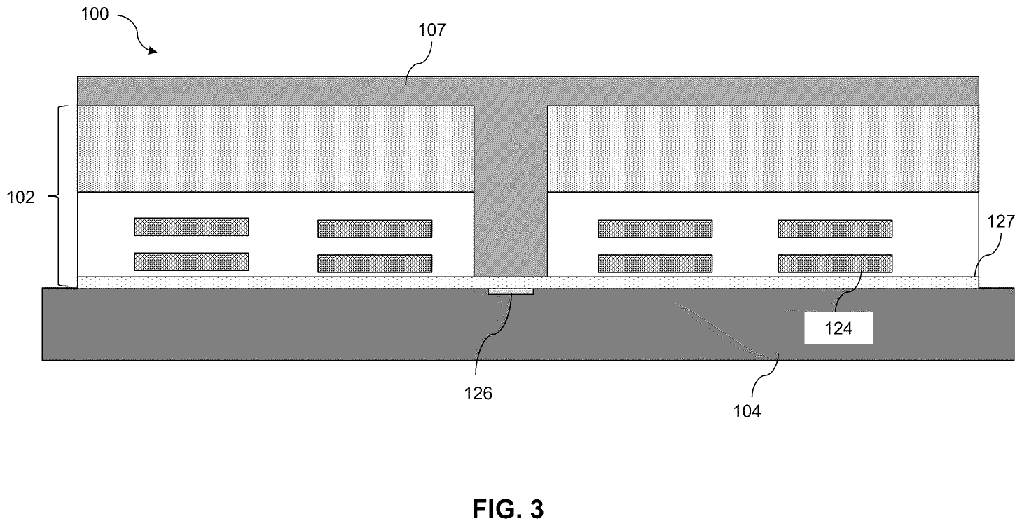

FIG. 3 illustrates an example of filling the alignment cavity 106 with a gap fill material 107 and additionally placing the gap fill material 107 above the RDL 102. In some embodiments, the gap fill material 107 may include a thermal gap filler, a high aspect ratio process material, an organosilane material, other appropriate material, or a combination thereof. The thermal gap filler may include a silicone base with fillers such as boron nitride, zinc oxide, or alumina and the gap fill is both heat generating and heat dissipating. The high aspect ratio process gap fill may include a thermal non-plasma based chemical vapor deposition process (CVD) with high aspect ratios which enhance transistor performance and reliability. The organosilance material may include cross-linked via oxygen and may be radiation-cured. The gap fill material 107 may be transparent or capable of being optically activated, such as by using photons, resulting in the alignment mark 126 being visible and/or detectable.

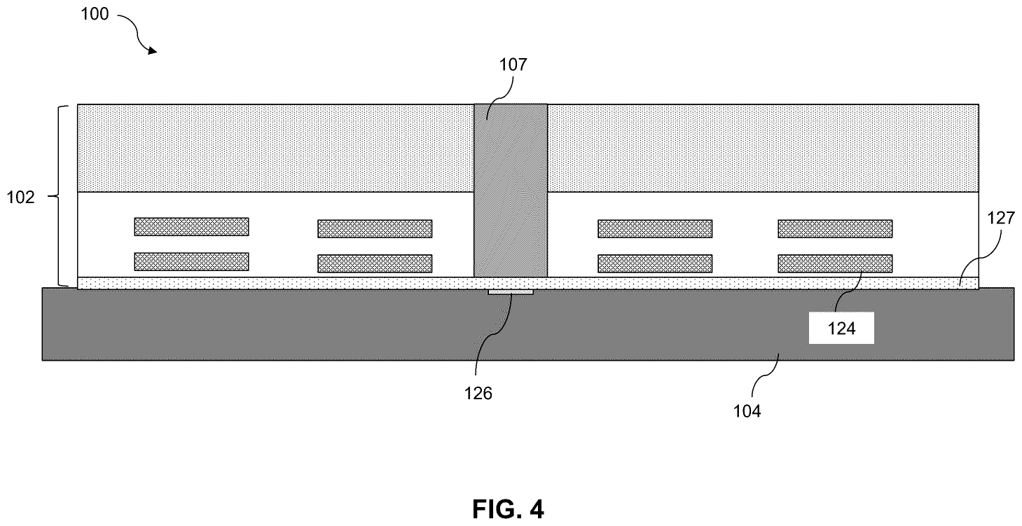

FIG. 4 shows a vertical-cross sectional view of a portion of the first-tier structure 100 after the gap fill material 107 is partially removed. In some embodiments, the gap fill material 107 is removed using a polishing process, such as chemical mechanical polishing (CMP). In other embodiments, the gap fill material 107 is removed using a dry or wet etching process, mechanical removal process, or other appropriate removal processes. Additionally, the silicon portion 110 may be thinned during the removal process. The resulting structure includes the top surface of the silicon portion 110 and the top surface of the gap fill material 107 being co-planar.

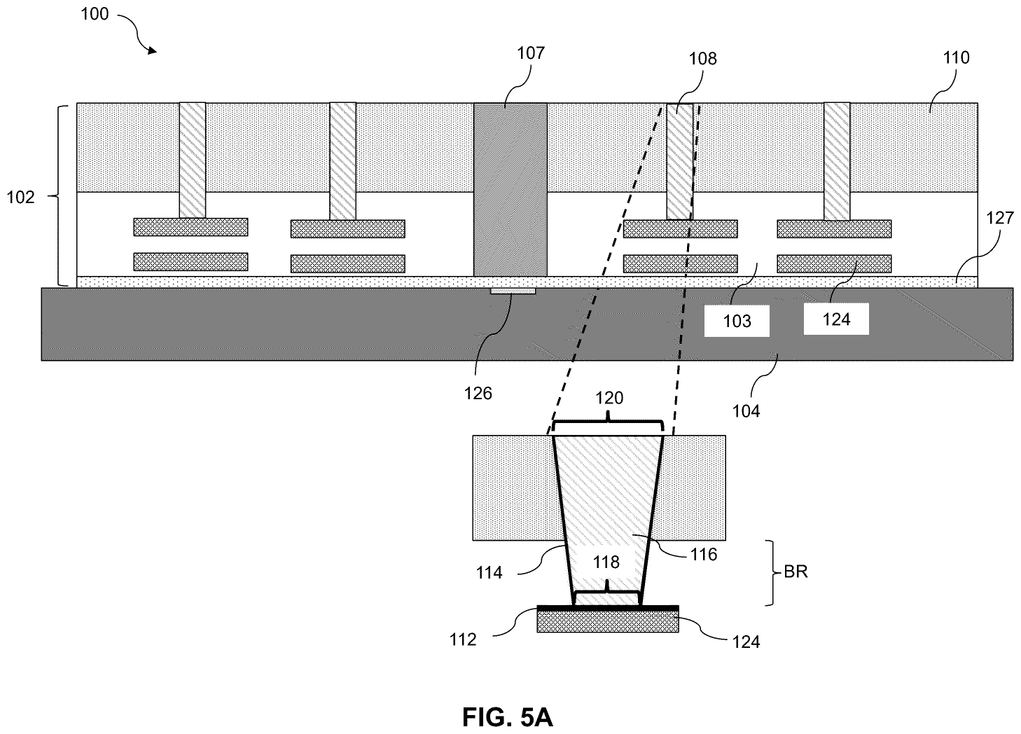

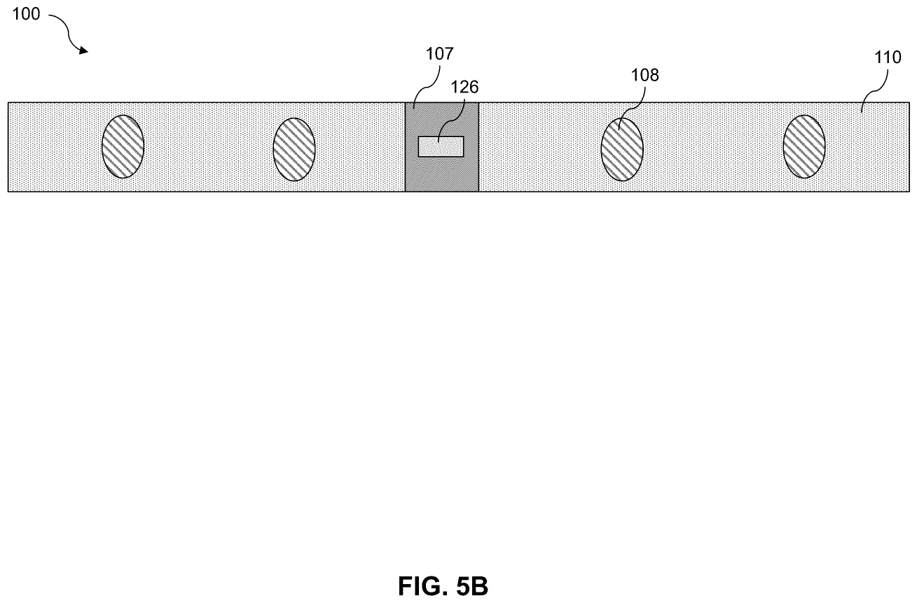

FIG. 5A is a vertical cross-sectional view illustrating the first-tier structure 100 with through-vias 108, including a close-up view of the through-vias 108, according to various embodiments of the present disclosure. Various embodiments of the present disclosure include forming last through-vias.

In some embodiments, the vertical through-vias 108 electrically couple different elements in the first-tier structure 100 and/or other tiers. For example, the through-vias 108 allow for routing of circuits across multiple tiers and provides efficient signal and power transitions.

To form the through-vias 108, a cavity is formed in the silicon portion 110 by a grinding, drilling, and/or patterning process. The cavity may further be formed through a portion of the dielectric layer 103. The location of the cavity may be determined based on the alignment mark 126. In more detail, a scanner, camera, or other device may identify the location of the alignment mark 126 and determine locations to form the cavities in the silicon portion 110 in relation to the location of the alignment mark 126. This ensures proper and consistent spacing of the cavities that may be used to subsequently form the through-vias 108.

The cavity may further extend beyond the silicon portion 110 to connect with the top metal 124 and form a bottom recess (BR). In some embodiments, the bottom recess (BR) is greater than about 10 Å, about 12 Å, or about 15 Å. The process to remove the silicon portion 110 and dielectric layer 103 may occur for a specific time such that a specific amount of the silicon portion 110 is removed. In other embodiments, the cavity formation process may continue until the dielectric barrier layer 112 on the top metals 124 is encountered.

The barrier layer 112 may protect the top metal 124 during the through-via 108 formation. For example, the cavity is formed to connect the through-via 108 to the top metal 124. The barrier layer 112 may protect the top metal when the patterning, drilling, or grinding process to form the cavities encounters the top metal 124. Additionally, the barrier layer 112 may further prevent diffusion from the top metal 124 into the dielectric layer 103. In some embodiments, only the top metals that are connected to through-vias 108 include the barrier layer 112. In other embodiments, every top metal may include a barrier layer 112. The barrier layer 112 may only be located above the top metal 124, partially surrounding the top metal 124, or fully surrounding the top metal 124. Further, the barrier layer 112 may be formed of tantalum (Ta), tantalum nitride (TaN), titanium nitride (TiN), or combinations thereof.

Optionally, once a portion of the silicon portion 110 and dielectric layer 103 is removed by the drilling, grinding, and/or patterning process to create the through-via cavities, a chemical mechanical polishing (CMP) process is used to further remove portions of the silicon portion 110 and smooth the through-via cavities. The CMP process combines chemical etching and abrasive polishing to create smooth surfaces. The CMP process may utilize a chemical mixture, such as a colloid, to remove excess silicon and create a smooth surface. Alternatively, the through-via cavities may be further smoothed using an epoxy dissolution to create a smooth surface.

Subsequently, a through-via barrier layer 114 may be deposited within the through-via cavity using chemical vapor deposition, atomistic vapor deposition, physical vapor deposition, or other deposition methods. In some embodiments the through-via barrier layer 114 may be formed of tantalum (Ta), tantalum nitride (TaN), titanium nitride (TiN), or combinations thereof. By providing a through-via barrier layer 114 within the through-via cavity, the barrier layer 112 above the top metal 124 may come into contact with the through-via barrier layer 114 in the through-via cavity. This connection between the through-via barrier layer 114 in the through-via cavity and the barrier layer 112 above the top metal 124 may form a dual barrier. The g may create a smooth surface to fill the through-via cavity with a conductive metal material 116. Further, the through-via barrier layer 114 may prevent diffusion from the conductive metal material 116 into the silicon portion 110 and dielectric layer 103.

In some embodiments, a conductive metal material 116 may be grown or filled in the through-via cavity to form the through-vias 108. The conductive metal material 116 may be copper, tungsten, silver, gold, or other appropriate conductive materials. The conductive metal material 116 may be grown in the through-via cavity by chemical vapor deposition, physical vapor deposition, sputtering, electroplating, or other appropriate methods. In this manner, the through-via 108 may comprise the through-via barrier layer 114 deposited in the through-via cavity and conductive metal material 116 deposited or grown in the through-via cavity.

As shown in FIG. 5A, a dual barrier may be formed where the through-via barrier layer 114 of the through-via 108 makes contact with the barrier layer 112 of the top metal 124. In some embodiments, the barrier layer 112 and the through-via barrier layer 114 may be formed of the same material, partially the same material, or different materials. The barrier layer 112 and through-via barrier layer 114 may act to minimize conductive metal material 116 diffusion, such as copper diffusion to the silicon portion 110, dielectric layer 103, and top metal 124. By limiting conductive metal material 116 migration, the dual barrier comprising the barrier layer 112 and through-via barrier layer 114 ensure structural integrity and reliability of the through-via 108.

Continuing to refer to the through-vias 108, in some embodiments, the conductive metal material 116 may allow different components to be stacked vertically within a semiconductor device by providing electrical connection between elements and across different layers of the semiconductor structure. Additionally, the conductive metal material 116 increases bandwidth, reduces signal delay, and improves power management. By filling the through-vias 108 with the conductive metal material 116, the through-vias 108 provide reliable and functional electrical connections between components disposed across multiple layers and/or tiers.

In some embodiments, the through-via 108 may have a reverse pillar shape, wherein a top width 120 (i.e., width of through-via 108 proximate to a subsequently formed BCBPM 122) of the through-via 108 is larger than a bottom width 118 of the through-via 108. For example, the ratio between the width of the bottom 118 (i.e., width of through-via 108 distal to a subsequently formed BCBPM 122) of the through-via 108 to the top 120 of the through-via 108 may be about 0.8, about 0.9, about 0.99, or less than about 1. In some embodiments, the through-via 108 includes a bottom recess (BR) where the through-via 108 extends beyond the silicon portion 110 into the dielectric layer 103. The bottom recess may be about 0.5 micrometers, about 1 micrometer, about 5 micrometers, about 8 micrometers, about 10 micrometers, or about 15 micrometers. The through-via 108 may have a circular, oval, square, rectangular, or other polygon horizontal cross-sectional shape. The width of the through-vias 108 may be optimized to provide electrical vias with the appropriate resistance for suitable electrical connections.

FIG. 5B illustrates a top-view of the through-vias 108 formed by the process described above in reference to FIG. 5A. As shown, the alignment mark 126 may be visible through the gap fill material 107 in the alignment cavity 106 by using a scanner, camera, or other appropriate methods. Subsequent to identifying the alignment mark 126, a location may be determined to form the through-via cavities, in which the through-vias 108 may be subsequently formed and located. The alignment mark 126 may ensure the through-vias 108 are formed at appropriate locations with consistent spacing.

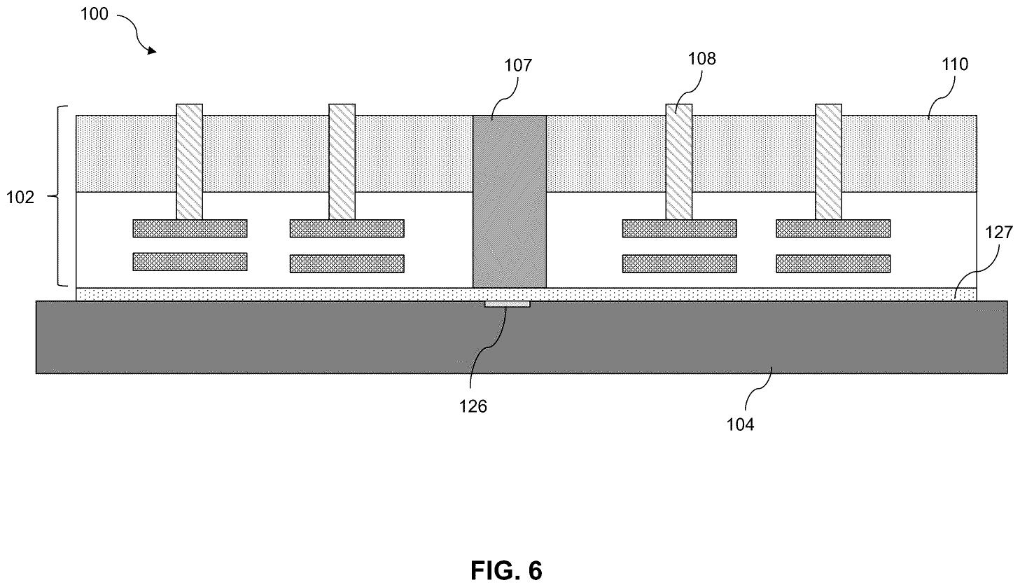

Referring to FIG. 6, an etch back process may be performed to remove a portion of the silicon portion 110 and expose a top portion of the through-vias 108. In some embodiments, the etch back process may be a wet etch or a dry etch process. A wet etching process may include applying a chemical solution to a surface which selectively removes certain materials, such as the silicon portion 110. The dry etching may include applying a gas or plasma to a material to selectively remove a material, such as the silicon portion 110. The etching process removes a top portion of the silicon portion 110 and partially exposes the through-vias 108.

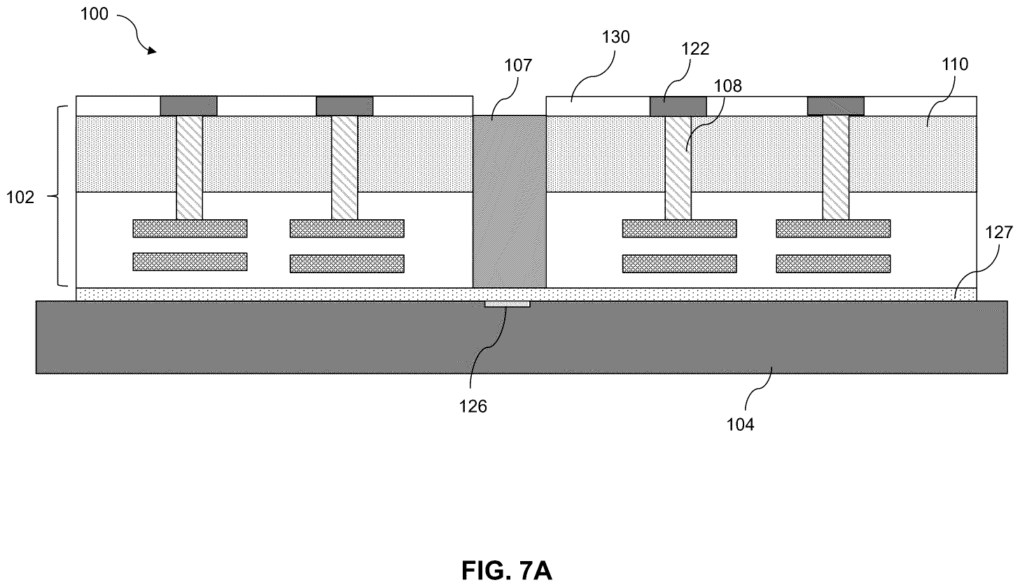

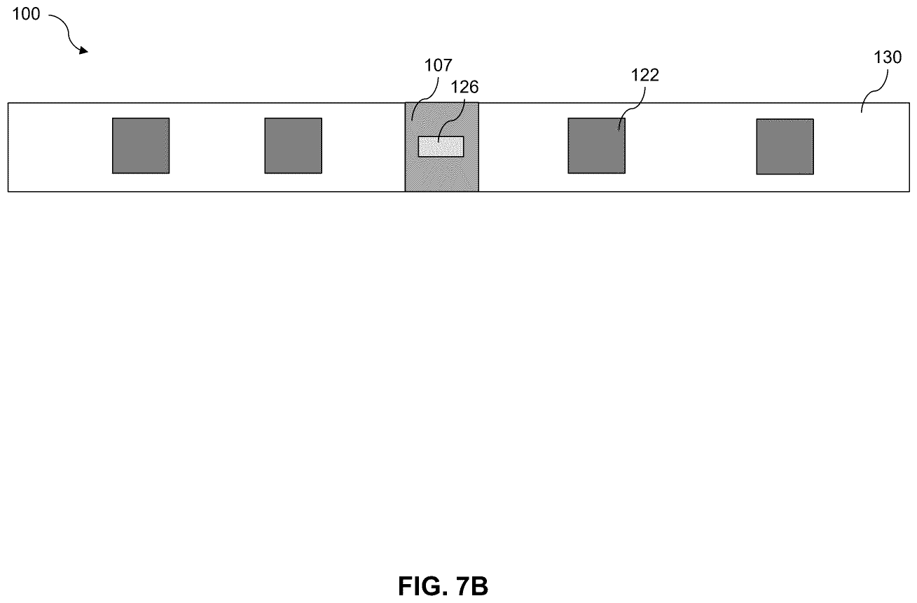

FIG. 7A is a vertical cross-sectional view illustrating the first-tier structure 100 after forming a backside bump pad metal (BSBPM) 122 in a capping layer 130, wherein the BSBPM 122 are aligned with the through-vias 108 based on the alignment mark 126 according to various embodiments of the present disclosure.

Initially, a dielectric layer 130, also referred to as a capping layer, may be formed above the silicon portion 110. The capping layer 130 may be patterned or drilled to form BSBPM cavities at locations that are determined based on the alignment mark 126 that correspond to the locations of the through-vias 108. A scanner may be used to identify the alignment mark 126 associated with the first carrier wafer 104. In this manner, the alignment mark 126 may be used to form both the through-vias 108 and the BSBPM 122. The alignment mark 126 may be identified with a different identification tool, however, the same alignment mark 126 may be still used to form both the through-vias 108 and the BSBPMs 122. In this manner, the location of the BSBPM 122 may be determined in relation to the same alignment mark 126 that may be used to determine the location of the through-vias 108. In doing so, the locations of the BSBPM 122 may be correlated to the locations of the through-vias 108. This process may promote enhanced alignment of the BSBPM 122 with the centers of the through-vias 108.

Optionally, the BSBPM cavities may further undergo a polishing process, such as CMP, to smooth the cavity surface. In some embodiments, the BSBPM 122 may be formed in the BSBPM cavities using a coating, exposure, and developing process. For example, a deposition method, electroplating, or sputtering method may grow or deposit a conductive metal within the BSBPM cavities to form the BSBPMs 122. In some embodiments, the conductive metals in the BSBPMs 122 are formed of copper, tungsten, gold, silver, other conductive metal, or combinations thereof, which provide electrical conductivity while also ensuring reliable connections between tiers and preventing oxidation.

The BSBPMs 122 may provide interconnections, improve reliability, and achieve a flat surface for connecting components in the final semiconductor package. Additionally, the BSBPMs 122 may provide improved density in interconnections particularly in complex semiconductor structures. The BSBPMs 122 may embed the exposed portions of the through-vias 108 and are therefore formed directly above and in contact with the silicon portion 110. In some embodiments, more BSBPMs 122 than through-vias 108 may be formed. In alternative embodiments, the number of through-vias 108 and BSBPMs 122 may be equal.

By forming the through-vias 108 as last through-vias, the alignment mark 126 associated with the first carrier wafer 104 is still available and physically associated to the location of the through-vias 108. Therefore, the BSBPM 122, may be properly aligned to the through-vias 108 using the same alignment mark 126. For these reasons, embodiments of the present disclosure improve the alignment between the through-vias 108 and the BSBPMs 122 by maintaining a physical correlation between the components based on the alignment mark 126. For example, a central axis of the through-via 108 may be aligned with a central axis of the BSBPM 122 within about 1 nm, within about 2 nm, within about 4 nm, within about 5 nm, or within more than 5 nm. For at least these reasons, disclosed embodiments advantageously improve alignment between the through-vias 108 and the BSBPMs 122 by using an alignment mark 126 on the first carrier wafer 104 after a PnP process on the first-tier structure 100.

FIG. 7B illustrates a top-view of the BSBPMs 122 aligned with the through-vias 108 based on the alignment mark 126. As shown, the alignment mark 126 on the first carrier wafer 104 is visible through the gap fill material 107 in the alignment cavity 106. Once the alignment mark 126 is identified, a location is determined where the BSBPMs 122 are formed. The determined location may result in the through-vias 108 being fully covered by and aligned with the BSBPMs 122. As shown, a central axis of the BSBPMs 122 may substantially be aligned with a central axis of the through-vias 108.

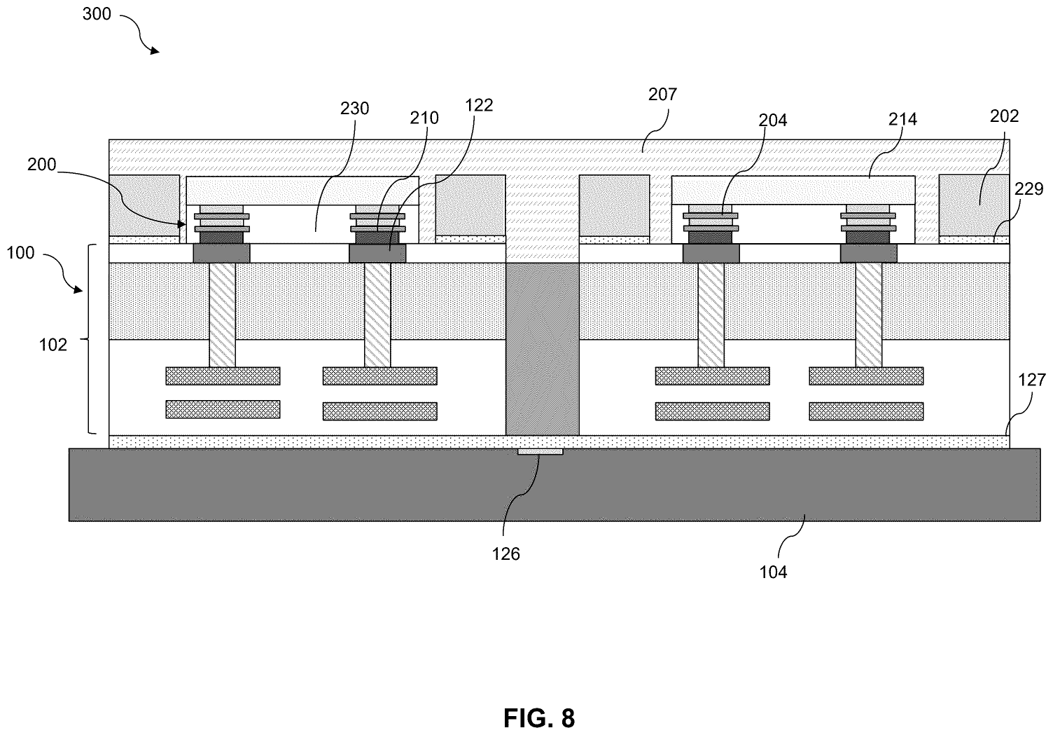

FIG. 8 is a vertical cross-sectional view illustrating the first-tier structure 100 bonded to a second-tier structure 200 that forms an intermediate semiconductor device 300 according to various embodiments of the present disclosure. The second tier structure 200 may be placed over the first tier structure 100 using a PnP process. The PnP process may utilize the alignment mark 126 located on the first carrier wafer 104 to align the second tier structure 200 with the first tier structure 100. In some embodiments, the second-tier structure 200 includes BPMs 210 and top metals 204 located within a dielectric layer 230 and a silicon portion 214 located above the dielectric layer 230.

The second-tier 200 structure may be bonded to the first-tier structure 100 through a hybrid bonding process. The hybrid bonding process, also referred to as direct bonding, directly bonds the second-tier structure 200 to the first-tier structure 100 by using metal-to-metal connections between the BSBPM portions 122 and the BPMs 210 and dielectric-to-dielectric bonding between dielectric layer 130 and dielectric layer 230. In some embodiments, each BSBPM portion 122 on the first-tier structure 100 may correspond to a BPM portion 210 on the second-tier structure 200.

Additionally, the intermediate semiconductor device 300 includes dies 202 (e.g., dummy dies, other active dies, or chips) that may be bonded and/or attached to the first-tier structure 100. The second-tier structure 200 and the dies 202 may be surrounded by a gap fill material 207. In some embodiments, the dies 202 may be divided by a plasma dicing process before being bonded to the first-tier structure 100. The plasma dicing process may include a dry etching process using chemical formulations, such as fluorine plasma, to etch dicing lanes. In other embodiments, the dies 202 may be divided using a blade dicing process, laser dicing process, or other appropriate dicing processes. In some embodiments, the dies 202 may be formed of silicon monoxide, silicon oxynitride, silicate, silicon dioxide, or other appropriate compounds.

Once the dies 202 are divided using the plasma dicing process, the dies 202 may be adhered to the first-tier structure 100 using an adhesive 229. Alternatively, in some embodiments, the dies 202 may be bonded to the first-tier structure 100 through a fusion bonding process, also known as direct bonding. The fusion bonding process includes a room-temperature pre-bonding stage where hydrogen bonds create initial interface bonds. Additionally, the fusion bonding process includes a high-temperature annealing stage where an annealing process facilitates formation of covalent bonds on the surfaces. In some embodiments, the dies 202 may provide structural and thermal management support during processing of the semiconductor structure 300.

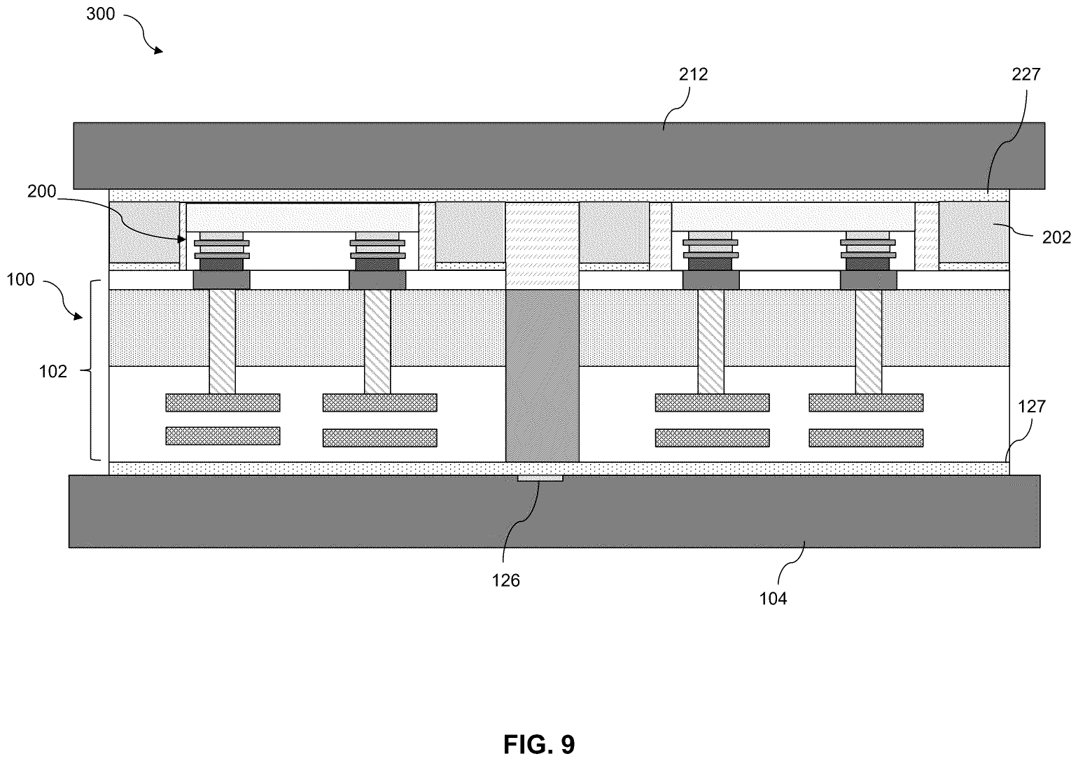

FIG. 9 is a vertical cross-sectional view illustrating the intermediate semiconductor device 300 after a second carrier wafer 212 is bonded above the second-tier structure 200 and the dies 202. The second carrier wafer 212 may be bonded to the second-tier structure 200 using an adhesive 227. In some embodiments, the adhesive 227 may be an epoxy glue layer or other appropriate adhesives. In other embodiments, the second carrier wafer 212 and the second-tier structure 200 may be bonded using other appropriate bonding techniques.

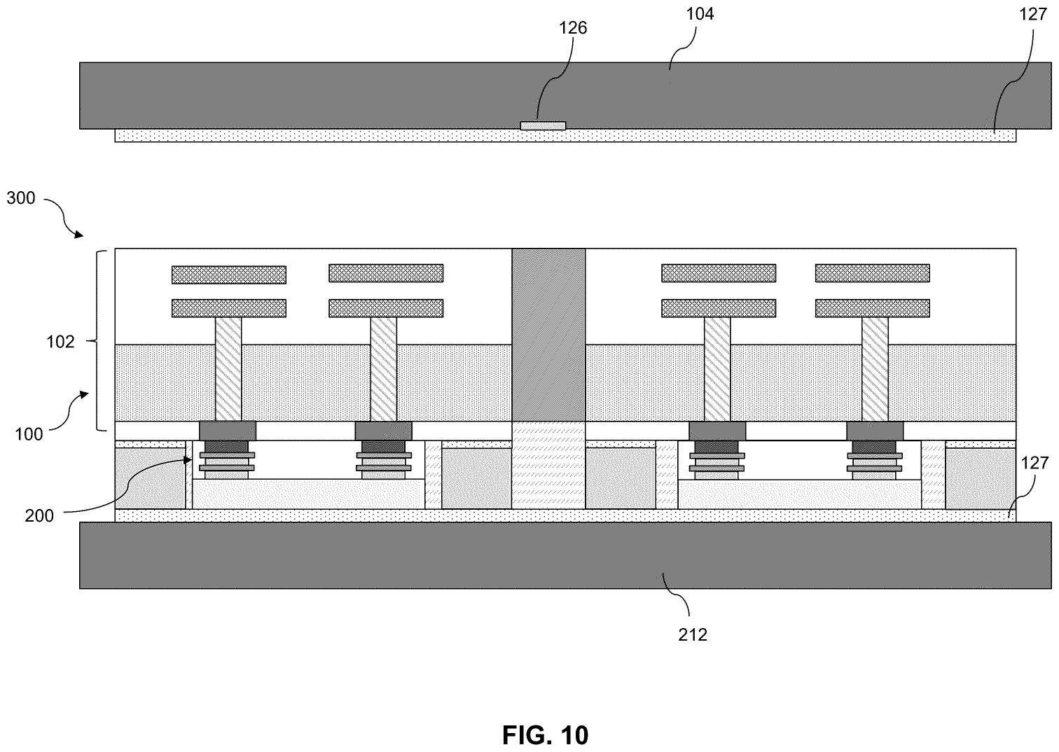

FIG. 10 illustrates a cross-sectional view after the first carrier wafer 104 has been removed and the entire semiconductor structure 300 has been inverted. In other words, the first-tier structure 100 is located above the second-tier structure 200 which may adhered to the second carrier wafer 212. In some embodiments, the first carrier wafer 104 may be removed by removing the glue layer or adhesive 127 through a chemical or mechanical process.

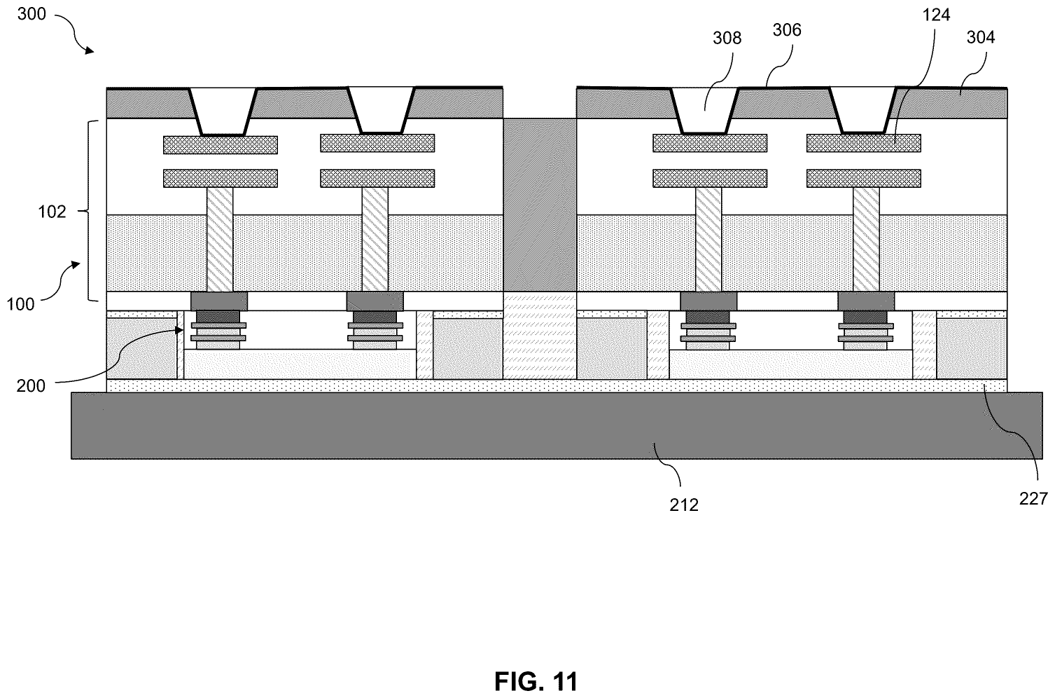

FIG. 11 illustrates a cross-sectional view of a passivation layer and a polyimide layer according to various embodiments of the present disclosure. In some embodiments, a passivation layer 304 may be formed over the first-tier structure 100. The passivation layer 304 may be formed of an oxide layer, a nitride layer, a borosilicate layer, a glass layer, other appropriate materials, or combinations thereof. The passivation layer 304 may enhance resistance to environmental factors and prevent degradation of the semiconductor device 300 to ensure long-term reliability. Further, the passivation layer 304 may provide a barrier that prevents metal layers from oxidizing and corroding.

In some embodiments, vias 308 may be formed through the passivation layer 304 that connect to the top metal 124 to other elements and form vertical electrical connections. Cavities may be formed in the passivation layer 304 using a patterning process. Once the cavities are formed, a polyimide layer 306 may be deposited along the top surface of the passivation layer 304 and within the cavities in which vias 308 are subsequently formed. The polyimide layer 306 may be deposited using chemical vapor deposition, physical vapor deposition, atomistic vapor deposition, or other appropriate deposition methods.

The polyimide layer 306 may provide thermal stability, electrical insulation, and mechanical strength to the semiconductor device 300. Further, the polyimide layer 306 may also provide mechanical elasticity, tensile strength, and enhance adhesion between devices for a stable connection. Even further, the polyimide layer 306 may provide a stress buffer to reduce thermal stress, a protective layer to shield the device 300 from environmental impacts, and as a high-temperature adhesive.

Subsequent to forming the polyimide layer 306, a conductive material is deposited or grown within the cavity using a deposition method, electroplating method, sputtering method, or other appropriate method to form the final vias 308.

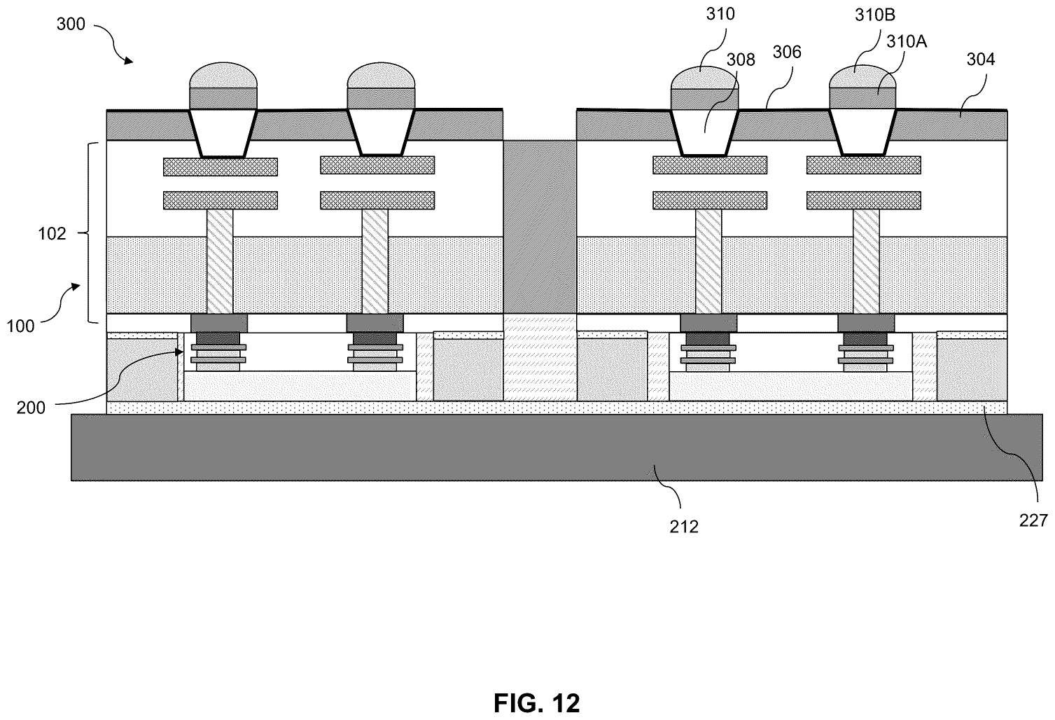

FIG. 12 illustrates an example of forming microbumps 310 above the vias 308 providing an electrical connection between the intermediate semiconductor structure 300 and elements in a final semiconductor package. In some embodiments, the microbumps 310 may be formed of a solder material, such as a tin alloy. The microbumps 310 may further include a solder pad 310A and a solder ball 310B located above the solder pad 310A. The microbumps 310 may connect to other components, devices, dies, or elements in a semiconductor package.

Referring now to FIGS. 13A and 13B, an example of the semiconductor device 400 coupled to a carrier substrate 406. The semiconductor device 400 may be coupled to the carrier substrate 406 by placing the semiconductor device 400 to align the microbumps 310 with bonding pads 427 formed on a carrier substrate 406. A reflow process may be performed to reflow the solder ball 310B to couple the micro bump 310 to the bonding pads 427 of the carrier substrate 406. The semiconductor device 400 may be formed by dicing the semiconductor structure 300 as described in FIGS. 1-12. FIG. 13A illustrates a vertical cross-sectional view of a semiconductor device 400 where the first-tier structure 100 is substantially aligned with the second-tier structure 200. FIG. 13B illustrates a vertical cross-sectional view of a semiconductor device 400 where the first-tier structure 100 is eccentric (i.e., slightly misaligned) from the second-tier structure 200 according to various embodiments of the present disclosure.

Additionally shown in the embodiments of FIGS. 13A and 13B, the first-tier structure 100 may further include additional devices 410 and additional inter metals 412 and the second-tier structure 200 includes additional device 424 and additional inter metals 426. In some embodiments, the additional devices 410, 424 may be formed within the silicon portions 110 and 214, respectively. The formation of the additional device 410, 424 may be performed prior to the formation of the through-vias 108, BSBPM 122 and/or the PnP process that places the second tier structure 200 over the first tier structure 100. The additional devices 410 and 424 may be capacitors, transistors, or other appropriate devices. The inter metals 426 and 412 may electrically connect the additional devices 410 and 424 to the dielectric layers 230 and 103, respectively.

As described above, the location of the through-vias 108 may be determined based on an alignment mark 126 on a first wafer carrier 104. After the through-vias 108 are formed, the BSBPMs 122 are formed based on the same alignment mark 126. Because the through-vias 108 and BSBPMs 122 are formed based on the same alignment mark 126 associated with the first wafer carrier 104, the through-vias 108 and BSBPMs 122 are substantially aligned. For example, a central axis of the through-vias 108 may be substantially aligned with a central axis of the BSBPMs 122. This improved alignment may provide more reliable electrical connections between the BSBPM 122 and through-via 108.

In more detail, the through-vias 108 have a reverse pillar shape where the width of the bottom portion 118 of the through-via 108 (i.e., portion of through-via 108 distal to the subsequently formed BSBPM 122) is smaller than the width of the top portion 120 of the through-via 108 (i.e., portion of through-via 108 proximate to the subsequently formed BSBPM 122). In some embodiments, a ratio between the width of the bottom portion 118 to the width of the top portion 120 is between about 0.9, about 0.99, or less than about 1. Additionally, the BSBPMs 122 may have a width that is larger than the width of the top portion 120 of the through-via 108. This further improves the alignment between the through-vias 108 and BSBPMs 122. The increased width of the BSBPM 122 may provide an enhance landing target for the second tier structure 200 to be placed over the first tier structure 100 in a PnP process. Such increased width of the BSBPM 122 may provide a wider margin of error in the event of a misalignment or eccentric alignment between the second tier structure 200 and first tier structure 100.

Therefore, embodiments of the present disclosure advantageously improve alignment of the through-vias 108 and BSBPMs 122 by forming both the through-vias 108 and the BSBPMs 122 based on the same alignment mark 126 associated with the first carrier wafer 104. Moreover, in some embodiments, the alignment may further be enhanced by also basing the location of the placement of a second tier structure 200 based on the same alignment mark 126. The improvements in alignment result in improved connectivity, stability, and efficiency in the multi-tiered semiconductor device 400.

In some embodiments, the BPMs 210 included in the second tier structure 200 may be aligned with the BSBPMs 122 included in the first tier structure 100 based on the alignment mark 126. Similarly, the BSBPMs 122 have a larger width than the BPMs 210 further improving alignment. As shown in FIG. 13A, the first-tier structure 100 and second-tier structure 200 are substantially aligned. In contrast, due to the alignment between the through-vias 108, BSBPMs 122, and BPMs 210, even when the first-tier structure 100 is not aligned with the second-tier structure 200, as shown in FIG. 13B, proper electrical connection still exists within the semiconductor device 400. In other words, regardless of whether the first-tier structure 100 is substantially aligned with the second-tier structure 200, the through-vias 108 maintain a proper electrical connection with the BSBPMs 122 and BPMs 210 providing a complete electrical connection through the first-tier structure 100 and second-tier structure 200. Therefore, misalignment due to PnP error, bonding error, or other manufacturing errors may be mitigated.

The following discussion now refers to a number of processes flows to form the bonded semiconductor device 300 or 400. Although the various processing steps are discussed in specific orders or are illustrated in a flow chart as occurring in a particular order, no order is required unless expressly stated or required because an act is dependent on another act being completed prior to the act being performed.

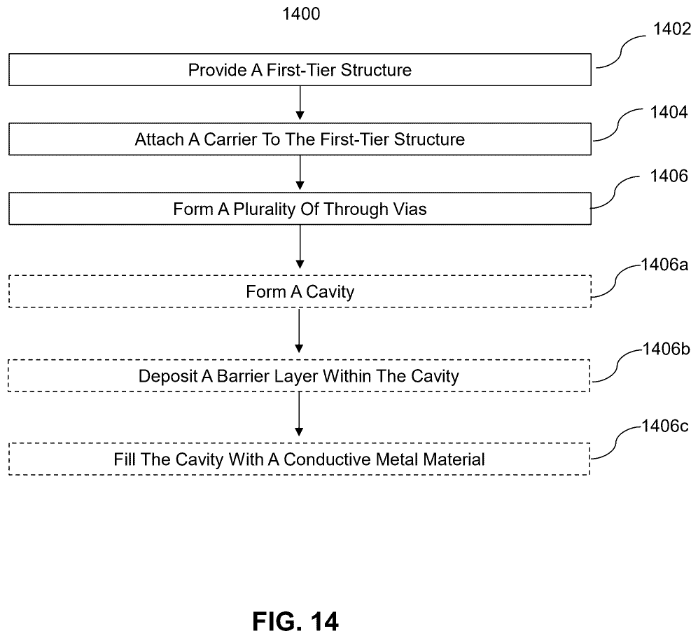

Embodiments are now described in connection with FIG. 14, which illustrates a flow diagram of example method 1400 for forming a through-via 108 in a semiconductor structure 300, 400. In some embodiments, step 1402 comprises providing a first-tier structure 100, where the first-tier structure 100 includes a silicon portion 110 and top metals 124. In some embodiments, additional device 410 may be formed in the silicon portion 110 and coupled to the top metals 124. In some embodiments, an alignment cavity 106 may also be formed in the first-tier structure 100.

In some embodiments, step 1404 includes attaching a first carrier wafer 104 to the first-tier structure 100. In some embodiments, the first carrier wafer 104 includes an alignment mark 126 that may be an overlay alignment mark or a backside mark and the alignment mark 126 is associated with the alignment cavity 106. Therefore, the alignment mark 126 may easily be identified through the alignment cavity 106 using a scanner, camera, or other appropriate identification methods.

In some embodiments, step 1406 includes creating a plurality of through-vias 108 that extend through at least the silicon portion 110 based on the alignment mark 126. Optionally, the through-vias 108 may extend through a portion of the dielectric layer 103. The location of the through-vias 108 may be based on the alignment mark 126 associated with the first carrier wafer 104. In some embodiments, a scanner is used to identify the alignment mark 126 and determine a location to form the through-vias 108. The through-vias 108 may be in direct contact with the top metals 124. More specifically, a through-via barrier layer 114 associated with the through-vias 108 may be in direct contact with barrier layer 112 associated with the top metals 124 to form a dual barrier structure.

Optionally, intermediate steps 1406a-d include forming the plurality of through-vias 108. In some embodiments, step 1406a includes forming a cavity through at least the silicon portion 110. In some embodiments, the cavity is formed using a patterning, grinding, or drilling process. In embodiments, the cavity formation process occurs until a concentration of a barrier layer 112 is contacted or for a predetermined amount of time. Additionally, the cavity may be formed through a portion of the dielectric layer 103 creating a bottom recess that may be at least 10 Å. Further, in some embodiments, the cavity may be polished using a CMP process after creating the initial cavity.

Step 1406b includes depositing a through-via barrier layer 114 within the cavity. In some embodiments, the through-via barrier layer 114 may be deposited using chemical vapor deposition, physical vapor deposition, atomistic vapor deposition or other deposition methods. Further, the through-via barrier layer 114 may be formed of tantalum (Ta), tantalum nitride (TaN), titanium nitride (TiN), or combinations thereof.

Step 1406c includes filling the cavity with a conductive metal material 116 to form the through-via 108. In some embodiments, the conductive metal material 116 may be formed or grown using an electroplating process, sputtering process, or deposition process. The conductive metal material 16 may be copper, tungsten, silver, gold, or other appropriate materials.

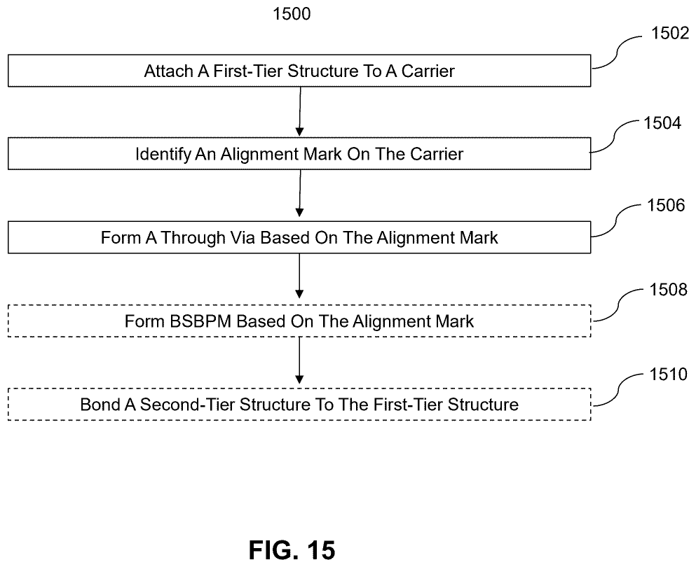

Embodiments are now described in connection with FIG. 15, which illustrates a flow diagram of example method 1500 for forming a through-via 108 with aligned BSBPMs 122 formed in a BSBPM layer 130. Referring to FIGS. 2, 5A, and 7A, in some embodiments, step 1502 includes attaching a first-tier structure 100 to a first carrier wafer 104. The first carrier wafer 104 may be bonded to the first-tier structure 100 through an adhesive 127 or other appropriate bonding methods.

Step 1504 includes identifying an alignment mark 126 on the first carrier wafer 104. In some embodiments, the alignment mark 126 is located on the first carrier wafer 104 and is within the alignment cavity 106 of the first-tier structure 100 allowing the alignment mark 126 to be easily identified. The alignment mark 126 may be identified using a scanner, camera, or other identification methods.

In some embodiments, step 1506 includes forming a through-via 108 in the first-tier structure 100, 400 based on the alignment mark 126. For example, the alignment mark 126 may be used to determine a location to form the through-vias 108 in the first-tier structure 100. In some embodiments, the through-vias 108 are formed through a silicon portion 110 of the first-tier structure 100. Additionally, the through-vias 108 may extend through a portion of the dielectric layer 103 to form a bottom recess.

Further, the method 1500 may include step 1508 of forming a BSBPM 122 substantially aligned with the through-via 108 based on the alignment mark 126. The same alignment mark 126 on the first carrier wafer 104 is used to form both the through-vias 108 and the BSBPMs 122. As a result, a central axis of the BSBPM 122 may be substantially aligned with a central axis of the through-vias 108.

Additionally, optional step 1510 includes bonding a second-tier structure 200 to the first-tier structure 100. The second tier structure 200 may be placed over the first tier structure 100 using the same alignment mark 126. Use of the same alignment mark 126 may enhance the alignment of the second tier structure 200 to the first tier structure 100. The second-tier structure 200 and the first-tier structure 100 may be bonded using a hybrid bond where the BSBPM 122 formed on the first tier structure 100 is bonded to the BPM 210 formed on the second tier structure 200 and the BSPM layer 130 (also referred to as a capping layer) is bonded to the dielectric layer 230. The alignment mark 126 may be used to align the BPM 210 to the BSBPM 122 resulting in improved alignment. Moreover, the increased width of the BSBPM 122 may provide a larger margin of error for placing the second tier structure 200 on the first tier structure 100. Therefore, the elements of the first-tier structure 100 and the second-tier structure 200 may be electrically connected through the BPM 210 and BSPM 122 even if the first-tier structure 100 and second-tier structure 200 are eccentric (see FIG. 13B). Referring to all drawings and according to various embodiments of the present disclosure, embodiments describe a semiconductor device 300, 400. The semiconductor device 300 comprises a first-tier structure 100, wherein the first-tier structure 100 comprises a plurality of through-vias 108 through a silicon portion 110 of the first-tier structure 100, wherein a top width 120 of the through-via 108 is larger than a bottom width 118 of the through-via 108, each of the plurality of through-vias 108 includes a through-via barrier layer 114; and a portion of the through-via barrier layer 114 is located between a conductive metal material 116 of the through-via 108 and a top metal barrier layer 122 of a top metal 124. The first-tier structure 100 further including a plurality of backside bump pad metals 122 coupled to the through-via 108. The semiconductor device 300, 400 further including a second-tier structure 200 bonded to the first-tier structure 100, wherein the second-tier structure 200 comprises: a plurality of bonding pad metals 210 bonded to the backside bonding pad metals 122 of the first-tier structure 100.

In some embodiments, a ratio between a bottom width 118 of the through-via 108 and a top width 120 of the through-via 108 is less than 1. In some embodiments, the through-vias 108 may have a bottom recess of at least about 10 Å. In some embodiments, an angle between a sidewall of the through via 108 and the bottom width 118 of the through-via 108 is larger than 90°. In some embodiments a central axis of each backside bump pad metal 122 is substantially aligned with a central axis of each through-via 108. In some embodiments, the central axis of each backside bump pad metal 122 is within about 5 nm of the central axis of each through-via 108. In some embodiments, a width of each backside bump pad metal 122 is greater than a width of a top portion of each of the through-vias 108.

An alternative embodiment describes a method 1400 of forming a semiconductor device 300, 400 the method includes providing a first-tier structure 100, wherein the first-tier structure 100 includes top metals 124; attaching the first-tier structure 100 to a first carrier wafer 104; and forming a plurality of through-vias 108 through a portion 110 of the first-tier structure 100 and in contact with the top metal 124.

In some embodiments, forming each through-via 108 includes: forming a cavity in the silicon portion 110 of the first-tier structure 100, forming a through-via barrier layer 114 within the cavity, and filling the cavity with a conductive metal material 116 to form the through-via 108. In some embodiments, the method includes identifying an alignment mark 126 on the first wafer carrier 104. In some embodiments, the method includes determining a location within the first-tier structure 100 to form the through-via 108 based on the alignment mark 126. In some embodiments, forming the through-via barrier layer 114 within the cavity forms a dual barrier layer with a barrier layer 112 associated with the top metal 124.

An alternative embodiment describes a method to align a backside bump pad metal 122 with a through-via 108 including attaching a first-tier structure 100 to a carrier wafer 104, identifying an alignment mark 126 on the first carrier wafer 104, and forming a through-via 108 in the first-tier structure 100 at a location relative to the alignment mark 126.

In some embodiments, the method includes etching back a portion of the first-tier structure 100 to expose a top portion of the through-via 108. In some embodiments the method includes forming a dielectric layer 130 over a top surface of the first-tier structure 100, wherein the backside bump pad metal is formed within the dielectric layer. In some embodiments, the method further includes forming a backside bump pad metal 122 at a location relative to the alignment mark 126 such that a central axis of the backside bump pad metal 122 is substantially aligned with a central axis of the through-via 108. In some embodiments, the method includes bonding a second-tier structure 200 to the first-tier structure 100 through a metal-to-metal bond and a dielectric-to-dielectric bond. In some embodiments, bonding the second-tier structure 200 to the first-tier structure 100 includes bonding a bond pad metal 210 in the second-tier structure 200 to the backside bump pad metal 122 based on the alignment mark 126. In some embodiments, forming each through-via 108 includes: forming a cavity in the silicon portion 110 of the first-tier structure 100, forming a through-via barrier layer 114 within the cavity, and filling the cavity with a conductive metal material 116 to form the through-via 108. In some embodiments, the method includes determining a location within the first-tier structure 100 to form the through-via 108 based on the alignment mark 126.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first-tier structure, wherein the first tier structure comprises:
a plurality of through-vias located through a silicon portion of the first-tier structure, wherein:
a top width of the through-via is larger than a bottom width of the through-via;
each of the plurality of through-vias includes a through-via barrier layer; and
a portion of the through-via barrier layer is located between a conductive metal material of the through-via and a top metal barrier layer; and
a plurality of backside bump pad metals respectively coupled to the plurality of through-vias, wherein;
a second-tier structure bonded to the first-tier structure, wherein the second-tier structure comprises:
a plurality of bonding pad metals respectively bonded to the plurality of backside bonding pad metals of the first-tier structure.

2. The semiconductor device of claim 1, wherein a ratio between the bottom width of the through-vias and the top width of the through-vias is less than 1.

3. The semiconductor device of claim 1, wherein an angle between a sidewall of the through-via and the bottom width of the through-via is larger than 90°.

4. The semiconductor device of claim 1, wherein a central axis of each of the plurality of backside bump pad metal is substantially aligned with a central axis of each through-via.

5. The semiconductor device of claim 4, wherein the central axis of each backside bump pad metal is within about 5 nm of the central axis of each through-via.

6. The semiconductor device of claim 4, wherein a width of each backside bump pad metal is greater than a width of a top portion of each of the through-vias.

7. A method of forming a semiconductor device, comprising:
providing a first-tier structure, wherein the first-tier structure includes top metals;
attaching the first-tier structure to a first carrier wafer; and
forming a plurality of through-vias through a silicon portion of the first-tier structure and in contact with the top metal.

8. The method of claim 7, wherein forming each through-vias further comprises:
forming a cavity in a silicon portion of the first-tier structure;
forming a through-via barrier layer within the cavity; and
filling the cavity with a conductive metal material to form the through-via.

9. The method of claim 8, wherein forming the cavity removes at least about 10 Å of a dielectric layer below the silicon portion to form a bottom a recess.

10. The method of claim 7, further comprising identifying an alignment mark on the first carrier wafer.

11. The method of claim 10, further comprising determining a location within the first-tier structure to form the through-via based on the alignment mark.

12. The method of claim 8, wherein forming the barrier layer within the cavity forms a dual barrier with a barrier layer associated with the top metal.

13. A method of aligning a backside bump pad metal with a through-via, comprising:
attaching a first-tier structure to a carrier wafer;
identifying an alignment mark on the first carrier wafer; and
forming a through-via in the first-tier structure at a location relative to the alignment mark.

14. The method of claim 13, further comprising etching back a portion of the first-tier structure to expose a top portion of the through-via.

15. The method of claim 13, further comprising forming a dielectric layer over a top surface of the first-tier structure, wherein the backside bump pad metal is formed within the dielectric layer.

16. The method of claim 13, further comprising forming a backside bump pad metal at a location relative to the alignment mark such that a central axis of the backside bump pad metal is substantially aligned with a central axis of the through-via.

17. The method of claim 13, further comprising bonding a second-tier structure to the first-tier structure through a metal-to-metal bond and a dielectric-to-dielectric bond.

18. The method of claim 15, wherein bonding the second-tier structure to the first-tier structure includes:
bonding a bond pad metal in the second-tier structure to the backside bump pad metal based on the alignment mark.

19. The method of claim 13, further comprising determining a location within the first-tier structure to form the through-via based on the alignment mark.

20. The method of claim 13, wherein forming each through-vias further comprises:
forming a cavity in a silicon portion of the first-tier structure;
forming a through-via barrier layer within the cavity; and
filling the cavity with a conductive metal material to form the through-via.
